(19) United States
(12) Patent Application Publication
(10) Pub. No.: US 2026/0305307 A1
(43) Pub. Date: Oct. 1, 2026

(54) VOLTAGE DIFFERENTIAL TOLERANT NET LINES IN SEMICONDUCTOR STRUCTURES

(71) Applicant: International Business Machines Corporation, Armonk, NY (US)

(72) Inventors: Hai Zhu, Poughkeepsie, NY (US); ATSUSHI OGINO, Fishkill, NY (US); Yueming Xu, Wappingers Falls, NY (US)

(21) Appl. No.: 19/095,670

(22) Filed: Mar. 31, 2025

(51) Int. Cl. H01L 23/528; H01L 21/768

(52) U.S. Cl. CPC H10W 20/43; H10W 20/056; H10W 20/063; H10W 20/074; H10W 20/081

(57) ABSTRACT

A semiconductor structure includes a first wiring layer having a first metal wire, the first metal wire having a recess defined therein; a second wiring layer having a second metal wire spaced a first distance from the first metal wire, and a third metal wire spaced a second distance from the first metal wire, the third metal wire being opposite the recess of the first metal wire; and an interlayer dielectric (ILD) separating the first wiring layer from the second wiring layer and the second metal wire from the third metal wire, in which a voltage differential tolerance between the first metal wire and the third metal wire is greater than a voltage differential tolerance between the first metal wire and the second metal wire.

### BACKGROUND

The present invention relates generally to the electrical, electronic, and computer arts, and, more particularly, to semiconductor structures and the like.

Semiconductor structures typically include multiple circuits used in a variety of microelectronic components. Such semiconductor structures can include metallic wiring that can connect individual devices within the semiconductor structure, creating a wiring interconnect network. Typically, the wiring interconnect network can include conductive features such as: lines, which can traverse a specific distance across the semiconductor structure; contacts; and vias, which can connect lines with lines in different layers (i.e., levels) of the semiconductor structure and/or with contacts. Further, semiconductor structures can include multiple patterned dielectric layers surrounding and separating the multiple layers of the conductive features, electrically insulating conductive features.

With continuing advancements in technology comes constant demands for both improved functionality and reduction in the size of semiconductor structures. As a consequence, there is a demand for reductions in a footprint of the interconnect structure that forms metallic circuitry within the semiconductor structure without jeopardizing functionality and reliability. One option to reduce the footprint of the interconnect structure is to minimize a separation between adjacent conductive features in the semiconductor structure. Additionally, incorporating multiple circuitries into one or more layers of the semiconductor structure can result in fewer overall layers of the semiconductor structure, yielding a smaller footprint. However, challenges have been observed when such circuitry includes a significant voltage differential between net lines in adjacent metal wires.

That is, when lines in one layer and adjacent lines in another layer of the semiconductor structure both are low voltage net lines, an adequate spacing and/or insulation between the layers, so as to minimize electrical interference such as cross-talk or shorting between the lines caused by time-dependent dielectric breakdown (TDDB) and/or electromigration, can be a specified distance and/or amount, respectively. However, when one of the lines is a high voltage net line, the potential for time-dependent dielectric breakdown (TDDB) between lines in adjacent layers increases due to the voltage differential between the lines. Thus, combining multiple circuitries that include at least one high voltage net line in one or more layers without jeopardizing functionality and reliability of the semiconductor structure can be challenging.

### BRIEF SUMMARY

Principles of the invention provide techniques for voltage differential tolerant NET lines in semiconductor structures. In one aspect, an exemplary semiconductor structure includes a first wiring layer having a first metal wire, the first metal wire having a recess defined therein, and a second wiring layer having a second metal wire, spaced a first distance from the first metal wire, and a third metal wire, spaced a second distance from the first metal wire, the third metal wire being opposite the recess of the first metal wire. The semiconductor structure further includes an interlayer dielectric (ILD) separating the first wiring layer from the second wiring layer and the second metal wire from the third metal wire, in which a voltage differential tolerance between the first metal wire and the third metal wire is greater than a voltage differential tolerance between the first metal wire and the second metal wire.

In another aspect, an exemplary semiconductor structure includes a first wiring layer having a first metal wire, the first metal wire being a first voltage net structure and having a recess defined therein, and a second wiring layer having a second metal wire, the second metal wire being a second voltage net structure, in which the second metal wire is opposite a non-recessed portion of the first metal wire, and a third metal wire, the third metal wire being a third voltage net structure, in which the third metal wire is opposite a recessed portion of the first metal wire. A distance between the third metal wire and the recessed portion of the first metal wire is greater than a distance between the second metal wire and the non-recessed portion of the first metal wire. The semiconductor structure further includes an interlayer dielectric (ILD) separating the first wiring layer from the second wiring layer and the second metal wire from the third metal wire, and a capping layer separating the first metal wire of the first wiring layer from the ILD. A voltage differential tolerance between the first metal wire and the third metal wire is greater than a voltage differential tolerance between the first metal wire and the second metal wire based on resistance to time-dependent dielectric breakdown (TDDB).

In yet another aspect, an exemplary method of forming a semiconductor structure includes forming a first wiring layer having a first metal wire, the first metal wire being a first voltage net structure; etching a recess in the first metal wire; depositing a capping layer over the first metal wire and the recess of the first metal wire; depositing an interlayer dielectric (ILD) on the capping layer; and forming a second wiring layer in the ILD. Forming the second wiring layer includes depositing a hard mask on the ILD and etching, within the ILD, a plurality of wiring patterns, in which a first wiring pattern of the plurality of wiring patterns is etched opposite a non-recessed portion of the first metal wire and a second wiring pattern of the plurality wiring patterns is etched opposite a recessed portion of the first metal wire. Forming the semiconductor structure further includes filling the first wiring pattern to form a second metal wire of the semiconductor structure, the second metal wire being a second voltage net structure, and filling the second wiring pattern to form a third metal wire of the semiconductor structure, the third metal wire being a third voltage net structure. The steps are carried out such that, subsequent to filling the second wiring pattern, the semiconductor structure is configured such that: a first voltage differential tolerance is provided between the first voltage net structure and the second voltage net structure; a second voltage differential tolerance is provided between the first voltage net structure and the third voltage net structure; and the second voltage differential tolerance is greater than the first voltage differential tolerance based on resistance to time-dependent dielectric breakdown (TDDB).

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages, and these potential advantages are not necessarily required of all embodiments. By way of example only and without limitation, one or more embodiments can provide a semiconductor structure that, without requiring addition of complex process steps or design nor increasing a distance between adjacent wiring layers, can support a low voltage net structure in a first wiring layer and an adjacent high voltage net structure in a second wiring layer with minimal-to-no electrical interference, such as cross-talk or shorting caused by time-dependent dielectric breakdown (TDDB), between the low voltage net structure and high voltage net structure:
by etching a recess in a metal wire of a first wiring layer at a location opposite a metal wire of an adjacent wiring layer when this metal wire is a high voltage net and other metal wires of the second wiring layer is/are a low voltage net,
by etching a recess in a metal wire of a first wiring layer with an area greater than the intersecting area between this metal wire and a metal wire in a second wiring layer located opposite the recess when this metal wire is a high voltage net and other metal wires of the second wiring layer is/are a low voltage net,
by creating a larger gap between a metal wire of a first wiring layer and a high voltage net metal wire of a second wiring layer than between the metal wire of the first wiring layer and a low voltage net metal wire of the second wiring layer,
by providing an increase in insulation between a metal wire of a first wiring layer and a metal wire of a second wiring layer when this metal wire is a high voltage net and other metal wires of the second wiring layer is/are a low voltage net,
by providing a greater insulation between a metal wire of a first wiring layer and a high voltage net metal wire of a second wiring layer than between the metal wire of the first wiring layer and a low voltage net metal wire of the second wiring layer,
by providing a greater thickness/amount of interlayer dielectric (ILD) between a metal wire of a first wiring layer and a high voltage net metal wire of a second wiring layer than between the metal wire of the first wiring layer and a low voltage net metal wire of the second wiring layer,
by depositing, filling at least in part, a recessed location of a first metal wire of a first wiring layer located opposite a metal wire of a second wiring layer, a dielectric material when this metal wire is a high voltage net and other metal wires of the second wiring layer is/are a low voltage net, or
by depositing, filling at least in part, a recessed location of a first metal wire of a first wiring layer located opposite a metal wire of a second wiring layer, a capping layer on the metal wire of a first wiring layer when this metal wire is a high voltage net and other metal wires of the second wiring layer is/are a low voltage net.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates an embodiment of wiring layers of a semiconductor structure;

FIGS. 2-5 illustrate exemplary embodiments of wiring layers of a semiconductor structure, according to aspects of the invention;

FIGS. 6A-6G illustrate an exemplary process for manufacturing wiring layers of a semiconductor structure according to the embodiment of FIG. 2, according to an aspect of the invention;

FIGS. 7A-7H illustrate an exemplary process for manufacturing wiring layers of a semiconductor structure according to the embodiment of FIG. 3, according to an aspect of the invention;

FIGS. 8A-8G illustrate an exemplary process for manufacturing wiring layers of a semiconductor structure according to the embodiment of FIG. 4, according to an aspect of the invention;

FIGS. 9A-9I illustrate an exemplary process for manufacturing wiring layers of a semiconductor structure according to the embodiment of FIG. 5, according to an aspect of the invention;

FIG. 10 illustrates a power supply diagram according to an embodiment of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Semiconductor structures can include conductive metallic wiring (hereinafter “metal wire”) such as contacts, vias, and lines, which can traverse a specific distance across the semiconductor structure, and the like. Metal wires can form circuitry which can connect individual devices internal and/or external to the semiconductor structure. That is, vias can connect one metal wire in one layer of the semiconductor structure to another metal wire in another layer. For example, vias can connect the lines in one layer of the semiconductor structure with lines in a different layer and/or with contacts of the semiconductor structure. Further, semiconductor structures can include dielectric layers that can physically separate and electrically insulate one circuit from another and/or one layer from another.

To minimize the size and/or increase functionality of the semiconductor structure, multiple individual circuitries can be incorporated within a single wiring layer of the semiconductor structure. As semiconductor structures often include both low voltage net and high voltage net circuits, combining both within a single wiring layer can be advantageous when attempting to reduce an overall amount of layers of the semiconductor structure and/or increase the functionality of the semiconductor structure.

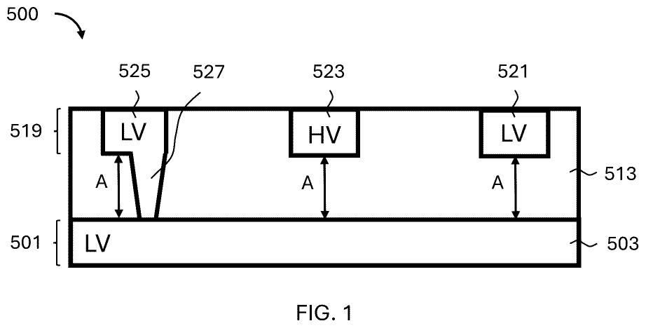

FIG. 1 illustrates a semiconductor structure 500 including an example of an approach that includes a low voltage net (LV) and a high voltage net (HV) within adjacent wiring layers. The term “high voltage net” as used herein, refers to a metal wire (i.e., circuitry) designed to have a voltage amount applied to the metal wire that is greater than a voltage amount applied to another metal wire (referred to as a low voltage net). In structures not using aspects of the invention, such a differential between the metal wire and the other metal wire (i.e., the low voltage net) can be sufficient to exceed a voltage differential tolerance and contribute to a time-dependent dielectric breakdown (TDDB) between the two metal wires.

Note that the skilled artisan will be familiar with techniques such as finite element analysis, and given the teachings herein, can select appropriate materials and geometries to meet TDDB design goals.

As shown in FIG. 1, a first wiring layer 501 of a semiconductor structure 500 can include a first metal wire 503. The first metal wire 503 can be a low voltage net. Adjacent to the first wiring layer 501, a second wiring layer 519 can include a second metal wire 521 and a third metal wire 523. The second metal wire 521 can be a low voltage net and the third metal wire 523 can be a high voltage net. In some scenarios, the second wiring layer 519 can include a fourth metal wire 525 having a via 527. The via 527 can physically and electrically connect at least a portion of the second wiring layer 519 to at least a portion of the first wiring layer 501 by connecting the fourth metal wire 525 of the second wiring layer 519 to the first metal wire 503 of the first wiring layer 501. Thus, the fourth metal wire 525 of the second wiring layer 519, the via 527, and the first metal wire 503 of the first wiring layer 501 can be, at least part of, one circuit.

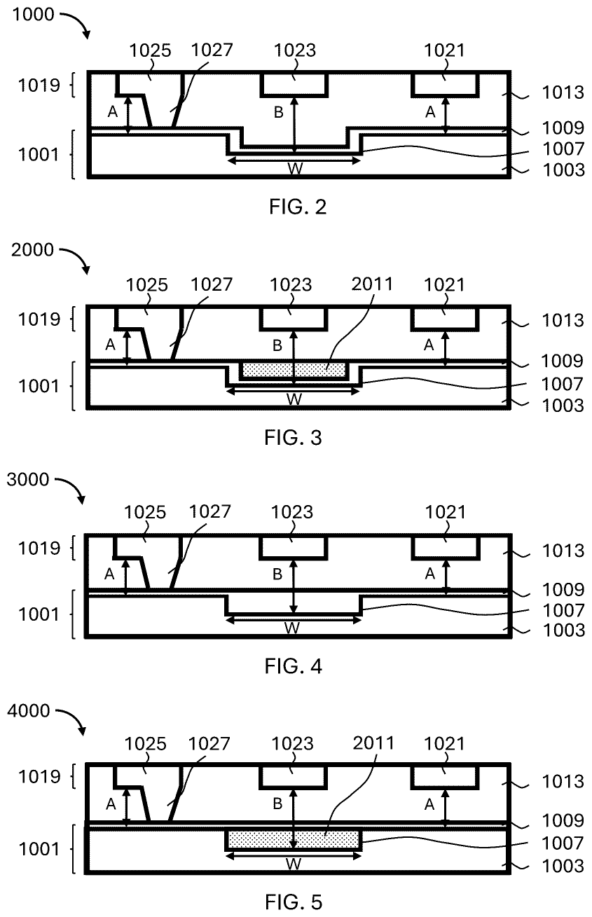

It is to be understood, that for brevity, the first metal wire 503 (and first metal wire 1003 as described in reference to FIGS. 2-5) and the second metal wire 521 (and second metal wire 1021 as described in reference to FIGS. 2-5) are described herein as low voltage nets, and the third metal wire 523 (and third metal wire 1023 as described in reference to FIGS. 2-5) is described herein as a high voltage net; however, examples are not so limiting. Accordingly, it is contemplated within the scope of the embodiments that the first metal wire 503 (and first metal wire 1003 as described in reference to FIGS. 2-5) and the second metal wire 521 (and second metal wire 1021 as described in reference to FIGS. 2-5) can be high voltage nets and the third metal wire 523 can be a low voltage net (and third metal wire 1023 as described in reference to FIGS. 2-5). Embodiments of the invention are broadly applicable to enhancing voltage differential tolerance between lines.

An interlayer dielectric (ILD) 513 can physically and electrically separate circuits within the semiconductor structure 500. That is, as shown in FIG. 1, the ILD 513 can physically separate and electrically insulate the second metal wire 521, the third metal wire 523, and the fourth metal wire 525 and can physically separate and electrically insulate the first metal wire 503 of the first wiring layer 501 from the second metal wire 521 and the third metal wire 523 of the second wiring layer 519. Accordingly, a first circuit can include the fourth metal wire 525 of the second wiring layer 519, the via 527, and the first metal wire 503 of the first wiring layer 501, a second circuit can include the third metal wire 523 of the second wiring layer 519, and a third circuit can include the second metal wire 521 of the second wiring layer 519. In an attempt to accommodate small semiconductor packages and/or complex functionality of the semiconductor structure 500, a smallest distance A between the first wiring layer 501 and the second wiring layer 519, without jeopardizing functionality and reliability of the semiconductor structure 500, can be beneficial.

That is, the smallest spacing and/or insulation thickness between the wiring layers 501 and 519 that can minimize electrical interference such as cross-talk or shorting between the metal wires 503, 521 caused by time-dependent dielectric breakdown (TDDB), can be advantageous. As used herein, the term “time-dependent dielectric breakdown (TDDB)” refers to a breakdown of a dielectric over time, caused when a voltage through a device is close to or beyond a specific tolerated amount, resulting in electron tunneling current forming a conductive path. TDDB of a dielectric between two adjacent metal wires can increase a potential for cross-talk and/or shorting between the two metal wires. As both the first metal wire 503 of the first wiring layer 501 and the second metal wire 521 of the second wiring layer 519 are low voltage nets (in the example), the distance A between the first metal wire 503 and the second metal wire 521, as shown in FIG. 1, can be sufficient as to not encounter cross-talk and/or shorting caused by TDDB.

However, when at least one of two adjacent metal wires is a high voltage net, due to the higher voltage of the high voltage net and the voltage differential between the low voltage net and the high voltage net, the potential for TDDB of the dielectric between the adjacent metal wires can be greater than when both metal wires are low voltage nets. As such, to prevent interference, such as cross-talk or shorting, between wiring layers that include a high voltage net line, an adequate distance between such wiring layers can be greater than that between two low voltage net lines (such as distance A as shown in FIG. 1).

One or more embodiments advantageously provide a semiconductor structure that includes both low voltage net and high voltage net circuits in adjacent wiring layers, without increasing a distance between the adjacent wiring layers nor overall thickness of the semiconductor structure and without jeopardizing functionality and reliability of the semiconductor structure due to time-dependent dielectric breakdown (TDDB).

Consider now an exemplary semiconductor structure according to aspects of the invention. Referring to FIGS. 2-5, a semiconductor structure 1000, 2000, 3000, 4000 can include a first wiring layer 1001 having a first metal wire 1003 and an adjacent second wiring layer 1019 having a second metal wire 1021, a third metal wire 1023, and in some embodiments, a fourth metal wire 1025, though examples are not so limited. The fourth metal wire 1025 can include a via 1027 electrically connecting the first wiring layer 1001 to the adjacent second wiring layer 1019 through a physical conductive connection between the fourth metal wire 1025 and the first metal wire 1003. In some embodiments, the first metal wire 1003 can be a low voltage net, though examples are not so limited as previously described in reference to FIG. 1. In some embodiments, the second metal wire 1021 can be a low voltage net and the third metal wire 1023 can be a high voltage net, though examples are not so limited as previously described in reference to FIG. 1. The first wiring layer 1001 and the second wiring layer 1019 can be separated by an interlayer dielectric (ILD) 1013. Note: terms such as “first,” “second,” “third,” and “fourth,” (e.g., first wiring layer and second wiring layer and/or first metal wire, second metal wire, third metal wire, and fourth metal wire) are used to indicate individual, separate structures as opposed to relative location or elevation in space. For example, FIGS. 1-5 illustrate the first wiring layer 1001 located below the second wiring layer 1019; however, examples are not so limiting and the second wiring layer 1019 can be located above, next to, adjacent to, etc. the first wiring layer 1001. Further, though FIGS. 1-5 illustrate three metal wires in the second wiring layer 1019 and one metal wire in the first wiring layer 1001, a single metal wire or multiple metal wires can be contemplated in one or both wiring layers.

In some embodiments, the first metal wire 1003 can include a recess 1007. The recess 1007 can be etched in the first metal wire 1003 at a location opposite the third metal wire 1023 (e.g., a high voltage net) of the adjacent second wiring layer 1019. Further, as the recess 1007 of the first metal wire 1003 is opposite the third metal wire 1023, a distance B between the first metal wire 1003 at the recess 1007 location and the third metal wire 1023 can be greater than a distance A between the first metal wire 1003 and the second metal wire 1021 and between the first metal wire 1003 and the fourth metal wire 1025. For example, in some non-limiting embodiments, distance A can be approximately 20 nm and distance B can be approximately 30-40 nm. However, examples are not so limiting, and distance B can depend on a voltage differential between a low voltage net and a high voltage net and/or the technology node of the semiconductor structure 1000, 2000, 3000, 4000 itself. For example, the greater the voltage differential, the greater the distance B between the first metal wire 1003 at the recess 1007 location and the third metal wire 1023 (i.e., the deeper the recess 1007). Additionally, to ensure, at least, the distance B across a width of the third metal wire 1023 from the first metal wire 1003, a width W of the recess 1007 can be greater than the width of the third metal wire 1023. Accordingly, the distance B (e.g., 30-40 nm) from the first metal wire 1003 of the first wiring layer 1001 to the high voltage net (i.e., third metal wire 1023) of the second wiring layer 1019 can be greater than the distance A (e.g., 20 nm) from the first metal wire 1003 of the first wiring layer 1001 to the low voltage nets (i.e., second metal wire 1021 and fourth metal wire 1025) of the second wiring layer 1019.

As shown in FIGS. 2-5, the semiconductor structure 1000, 2000, 3000, 4000 can further include a capping layer 1009 located between the first metal wire 1003 of the first wiring layer 1001 and the ILD 1013, separating the first metal wire 1003 from the ILD 1013. The capping layer 1009 can aid in prevention of electromigration of the first metal wire 1003 into the ILD 1013.

In some embodiments, a distance A between the first metal wire 1003 and both the second metal wire 1021 and the fourth metal wire 1025 can correspond to a minimal sufficient thickness of the ILD 1013 and the capping layer 1009 in which any TDDB between the metal wiring 1003, 1021 does not affect an integrity (e.g., create potential cross-talk or shorting opportunities) of the electrical isolation between the first metal wire 1003 and the second metal wire 1021. As such, the distance between the capping layer 1009 and both the second metal wire 1021 and the fourth metal wire 1025 can correspond to a distance between the first wiring layer 1001 and the second wiring layer 1019.

Referring now to FIG. 2. In some embodiments, the capping layer 1009 of the semiconductor structure 1000 can extend along a surface of the first metal wire 1003 including side walls and across a surface of the recess 1007, partially filling the recess 1007 of the first metal wire 1003. The ILD 1013 between the first wiring layer 1001 and the second wiring layer 1019 can fill an area between the capping layer 1009 and the second wiring layer 1019 including a remaining area of the recess 1007 not filled by the capping layer 1009.

Accordingly, in some embodiments, the distance B between the first metal wire 1003 and the third metal wire 1023 can be dependent upon a voltage differential tolerance of the ILD 1013 and the capping layer 1009 located between the first metal wire 1003 and the third metal wire 1023. The distance B between the first metal wire 1003 and the third metal wire 1023 can thus correspond to at least a minimal sufficient thickness of the ILD 1013 and the capping layer 1009 in which any TDDB between the metal wiring 1003, 1023 does not affect an integrity (e.g., create potential cross-talk or shorting opportunities) of the electrical isolation between the first metal wire 1003 and the third metal wire 1023. Further, a minimal depth of the recess 1007 can, therefore, be dependent upon the minimal sufficient thickness of the ILD 1013 and the capping layer 1009 in which TDDB does not affect integrity of the circuitry of the semiconductor structure 1000. Therefore, the depth of the recess 1007 can be dependent upon voltage magnitudes applied to the first metal wire 1003 and the third metal wire 1023 of the semiconductor structure 1000 (and semiconductor structures 2000, 3000, and 4000 as described below in reference to FIGS. 2-4, respectively) and the dielectric.

For example, the magnitude of the voltage at which the first metal wire 1003 is maintained and the magnitude of voltage at which the third metal wire 1023 is maintained can be a factor in determining the depth of the recess 1007. That is, non-limiting factors in determining the depth of the recess 1007 can include a potential for a TDDB caused by the magnitude of voltage of the first metal wire 1003 and the third metal wire 1023, and functional requirements of the first metal wire 1003 (e.g., excessive recessing of the first metal wire 1003 can create disruption to the first metal wire 1003). In some examples, the depth of the recess 1007 can be up to 50% of a depth of the first metal wire 1003 (e.g., 10-50%, or 20-50%, or 30-50%, or 40-50%), but this is to be taken as exemplary and non-limiting—other examples can have a different depth value. In some embodiments, such as in advanced technology nodes, the depth of the recess 1007 can be approximately 50%, though embodiments are not so limiting. In still further non-limiting embodiments, such as in legacy technology nodes, the depth of the recess 1007 can be less than 50%. The recess depth is flexible in one or more embodiments, and can be determined so it meets the high voltage differential tolerance requirement but not to create too much disruption to the bottom metal wire.

Referring now to FIG. 3. In some embodiments, similar to the capping layer 1009 as shown in FIG. 2, the capping layer 1009 of the semiconductor structure 2000 can extend along a surface of the first metal wire 1003 including side walls and across a surface of the recess 1007, partially filling the recess 1007 of the first metal wire 1003. The semiconductor structure 2000 can further include a dielectric material 2011 that fills a remaining area of the recess 1007 not filled by the capping layer 1009. As such, the ILD 1013 can separate the first wiring layer 1001 from the second wiring layer 1019 by filling, at a non-recessed portion of the first metal wire 1003 of the first wiring layer 1001, an area between the capping layer 1009 and the second wiring layer 1019 and by filling an area between the dielectric material 2011 and the second wiring layer 1019.

Accordingly, in some embodiments, the distance B between the first metal wire 1003 and the third metal wire 1023 can be dependent upon a voltage differential tolerance of the ILD 1013, the capping layer 1009, and the dielectric material 2011 located between the first metal wire 1003 and the third metal wire 1023. The distance B between the first metal wire 1003 and the third metal wire 1023 can thus correspond to at least a minimal sufficient thickness of the ILD 1013, the dielectric material 2011, and the capping layer 1009 in which any TDDB between the metal wiring 1003, 1023 does not affect an integrity (e.g., create potential cross-talk or shorting opportunities) of the electrical isolation between the first metal wire 1003 and the third metal wire 1023. Further, a minimal depth of the recess 1007 (e.g., in a non-limiting example, up to 50% of the depth of the first metal wire 1003, depending of factors such as technology node, as described in reference to FIG. 2) can, therefore, be dependent upon the minimal sufficient thickness of the ILD 1013, the dielectric material 2011, and the capping layer 1009 in which TDDB does not affect integrity of the circuitry of the semiconductor structure 2000.

FIG. 4 illustrates another exemplary semiconductor structure 3000 embodiment that can include the capping layer 1009 in which the capping layer 1009 extends along a surface of the first metal wire 1003 and fills the recess 1007 of the first metal wire 1003. As illustrated in FIG. 4, the ILD 1013 can fill an area between the capping layer 1009 and the second wiring layer 1019 of the semiconductor structure 3000. Accordingly, in some embodiments, the distance B between the first metal wire 1003 and the third metal wire 1023 can be dependent upon a voltage differential tolerance of the ILD 1013 and the capping layer 1009 located between the first metal wire 1003 and the third metal wire 1023. The distance B between the first metal wire 1003 and the third metal wire 1023 can thus correspond to at least a minimal sufficient thickness of the ILD 1013 and the capping layer 1009 in which any TDDB between the metal wiring 1003, 1023 does not affect an integrity (e.g., create potential cross-talk or shorting opportunities) of the electrical isolation between the first metal wire 1003 and the third metal wire 1023. Further, a minimal depth of the recess 1007 (e.g., in a non-limiting example, up to 50% of the depth of the first metal wire 1003, depending of factors such as technology node, as described in reference to FIG. 2) can, therefore, be dependent upon the minimal sufficient thickness of the ILD 1013 and the capping layer 1009 in which TDDB does not affect integrity of the circuitry of the semiconductor structure 3000.

Turning now to FIG. 5. In some embodiments, the semiconductor structure 4000 can include the dielectric material 2011. As shown in FIG. 5, the dielectric material 2011 can fill the recess 1007 of the first metal wire 1003. The capping layer 1009 of the semiconductor structure 4000 can extend along the surface of the non-recessed portion of the first metal wire 1003 and a surface of the dielectric material 2011, separating the first metal wire 1003 and the dielectric material 2011 from the second wiring layer 1019.

Accordingly, in some embodiments, the distance B between the first metal wire 1003 and the third metal wire 1023 can be dependent upon a voltage differential tolerance of the ILD 1013, the capping layer 1009, and the dielectric material 2011 located between the first metal wire 1003 and the third metal wire 1023. The distance B between the first metal wire 1003 and the third metal wire 1023 can thus correspond to at least a minimal sufficient thickness of the ILD 1013, the capping layer 1009, and the dielectric material 2011 in which any TDDB between the metal wiring 1003, 1023 does not affect an integrity (e.g., create potential cross-talk or shorting opportunities) of the electrical isolation between the first metal wire 1003 and the third metal wire 1023. Further, a minimal depth of the recess 1007 (e.g., in a non-limiting example, up to 50% of the depth of the first metal wire 1003, depending of factors such as technology node, as described in reference to FIG. 2) can, therefore, be dependent upon the minimal sufficient thickness of the ILD 1013, the capping layer 1009, and the dielectric material 2011 in which electromigration does not affect integrity of the circuitry of the semiconductor structure 4000.

Thus, an area between the high voltage net (e.g., third metal wire 1023) of the second wiring layer 1019 can have a greater amount of insulation between and a greater distance from the first metal wire 1003 of the first wiring layer 1001 without increasing an overall distance between the first wiring layer 1001 and the second wiring layer 1019.

Consequently, combining of low voltage nets and high voltage nets within a single wiring layer (e.g., second wiring layer 1019) of the semiconductor structure 1000, 2000, 3000, 4000 as shown in the embodiments illustrated in reference to FIGS. 2-5, can allow for the potential of a reduction in a quantity of wiring layers within the semiconductor structure 1000, 2000, 3000, 4000 and/or can increase a potential for a greater functionality (e.g., increased circuitry, wiring layout flexibility, etc.) of the semiconductor structure 1000, 2000, 3000, 4000 without increasing a distance between wiring layers 1001, 1019 and wasting valuable space and materials such as dielectrics and/or metallization (e.g., via 1027) between adjacent wiring layers 1001, 1019. Further, since in such embodiments the distance A between the first metal wire 1003 and the fourth metal wire 1025 is not increased with the introduction of the high voltage net, third metal wire 1023, a height of, and in turn an amount of material used in, the via 1027 connecting the first metal wire 1003 to the fourth metal wire 1025 is also not increased. This can be advantageous as longer vias and a thicker ILD can cause an increase in resistance across the vias and/or opens in vias. As such, the introduction of the high voltage net, third metal wire 1023, as described herein, does not increase a resistance between the first metal wire 1003 and the fourth metal wire 1025, which can adversely affect any circuitry that includes the first metal wire 1003 and the fourth metal wire 1025.

As described previously in reference to FIG. 1, though embodiments described herein include the first metal wire 1003 as a low voltage net and the third metal wire 1023 as a high voltage net, embodiments are not so limited. As such, though not described for brevity, the first metal wire 1003 can be a high voltage net while the third metal wire 1023 can be a low voltage net. Accordingly, in such embodiments, the recess 1007 of the first metal wire 1003 (i.e., a high voltage net) can be opposite the third metal wire 1023 (i.e., a low voltage net).

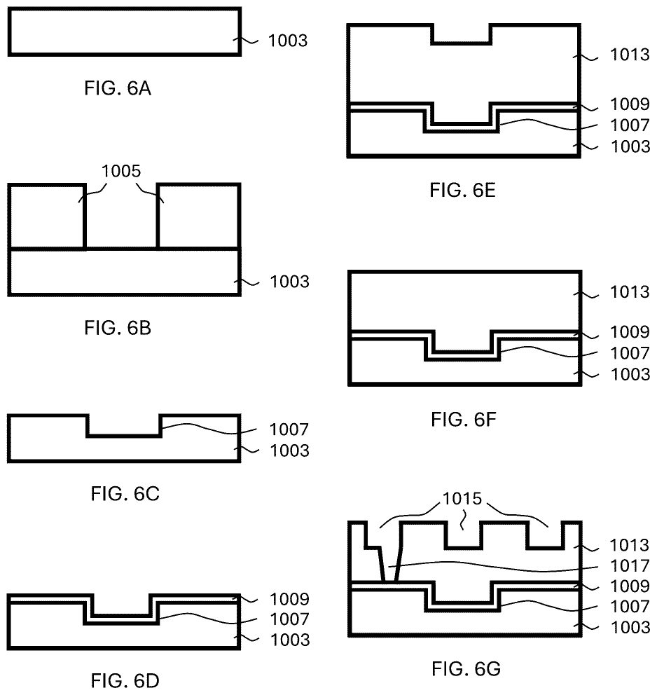

Referring now to FIGS. 6A-6G, according to some aspects, in the method of manufacturing a semiconductor structure, according to the embodiment of FIG. 2, a first metal wire 1003 can be formed, as shown in FIG. 6A. The first metal wire 1003 can be formed in a first wiring layer (e.g., first wiring layer 1001 as illustrated in FIG. 2) on a substrate (not shown for simplicity) of the semiconductor structure utilizing processes known in the art (e.g., Damascene process, etc.).

As further illustrated in FIG. 6B, a patterned mask 1005 can be formed on the first metal wire 1003. For example, a layer of photoresist can be deposited on the first metal wire 1003 utilizing techniques known in the art such as spin-coating, though examples are not so limited. In some embodiments, the photoresist can be a positive or a negative resist utilizing materials known in the art, such as but not limited to poly(methyl methacrylate), poly(methyl glutarimide), SU-8, etc. Utilizing known photolithography processes, such as optical or immersion photolithography, deep or extreme UV lithography, etc., the photoresist layer can be patterned to provide a template (e.g., areas in the photoresist that include little to no photoresist) for etching of the first metal wire 1003. In some embodiments, the patterned mask 1005 can include a stack of materials layers, such as photoresist, sacrificial hard mask, etc., though embodiments are not so limited.

As shown in FIG. 6C, the patterned mask (e.g., patterned mask 1005 as shown in FIG. 6B) and a portion of the first metal wire 1003 can be etched utilizing processes known in the art, such as but not limited to wet etching, plasma based dry etching, etc. Accordingly, the patterned mask can be removed and a selective portion of the first metal wire 1003 can be etched to form a recess 1007 in the first metal wire 1003. A width of the recess 1007 can correspond to the template of the patterned mask. In some embodiments, the recess 1007 can be etched to a particular depth (as previously described in reference to FIGS. 2-5) and a particular width that corresponds to an adjacent metal wire (e.g., third metal wire 1023 as previously described in reference to FIG. 2) of a wiring layer adjacent to the first wiring layer (e.g., second wiring layer 1019 as shown in FIG. 2). That is, the dimensions of the recess 1007, depth and width, can correspond to a minimal sufficient insulation between the first metal wire 1003 and the adjacent high voltage net metal wire, as described in reference to FIG. 2.

In some embodiments, a capping layer 1009 can be deposited over the first metal wire 1003, as illustrated in FIG. 6D. The capping layer 1009 can be a metal capping layer 1009 and can include SiC, SiₓCN, SiₓN, AlₓO, AlN, or AlₓON, though examples are not so limiting. The capping layer 1009 can be deposited over the first metal wire 1003 utilizing processes known in the art, such as but not limited to chemical vapor deposition (CVD), plasma-enhanced chemical vapor deposition (PECVD), atomic layer deposition (ALD), physical vapor deposition (PVD), electroless deposition, etc., though examples are not so limited. The capping layer 1009 can extend along a surface of the first metal wire 1003 including side walls and across a surface of the recess 1007, partially filling the recess 1007 of the first metal wire 1003.

Turning to FIG. 6E, an interlayer dielectric (ILD) 1013 can be deposited over the capping layer 1009. The ILD 1013 can be made of silicon-oxide (SiOₓ) or a low-k dielectric, though examples are not so limited and the ILD 1013 can be made of any material suitable for use as an interlayer dielectric. For example, the ILD 1013 can include a low-k dielectric with a K≤4, such as SiₓC(OH)_{y}, SiₓCNH_{y}, or SiₓCN(OH)_{y}, though examples are not so limiting. Further, the ILD 1013 can be deposited utilizing techniques known in the art, such as but not limited to sputtering, plasma deposition, CVD anodization, spin on, etc. In some embodiments, the ILD 1013 can fill the remaining area of the recess 1007 of the first metal wire 1003.

Continuing on to FIG. 6F, chemical mechanical polishing (CMP) and/or planarization processes can be performed on the ILD 1013, removing excess ILD 1013 material. A hard mask can be formed on the remaining ILD 1013 utilizing processes known to one skilled in the art including but not limited to PVD, CVD, ALD, plating, and the like. The hard mask can be patterned, such as by a photoresist deposition, light exposure, and photoresist removal process, though examples are not so limited. Based on the patterning, the hard mask and ILD 1013 can be etched (utilizing process known in the art such as dry etch, wet etch, etc.) to create a plurality of wiring patterns, such as a trench 1015 and a via 1017 patterning as shown in FIG. 6G. In some embodiments, any remaining hard mask can be removed during or after completion of the etching process.

Referring back to FIG. 2. Metal can be deposited, filling the plurality of wiring patterns (e.g., trench 1015 and via 1017 patterning as shown in FIG. 6G) and forming the second wiring layer 1019. In some embodiments, the metal can be made of Copper (Cu), Ruthenium (Ru), Tungsten (W), and/or Cobalt (Co), though examples are not so limited. Further, the metal can be deposited utilizing processes known in the art, such as but not limited to PVD, CVD, ALD, or plating. In some examples, prior to depositing of the metal, a barrier layer (not shown to avoid clutter) can be deposited on the ILD 1013. The barrier layer can aid in separation between the metal and the ILD 1013 and prevention of electromigration of the metal into the ILD 1013. The barrier layer can be deposited utilizing PVD, CVD, or ALD processes, though examples are not so limited, and can include tantalum-nitride (TaN), titanium (Ti), titanium-nitride (TiN), Co, and/or manganese (Mn), though examples are not so limited. The skilled artisan will be familiar with barrier layer technology, and, given the teachings herein, can select a suitable barrier layer material and deposit/apply same as appropriate.

As shown in FIG. 2, the deposited metal can form the second metal wire 1021, the third metal wire 1023, the fourth metal wire 1025, and the via 1027. Excessive metal (and barrier layer in embodiments that include a barrier layer) deposited on the ILD 1013 can be removed using chemical mechanical polishing (CMP) and/or planarization processes known in the art.

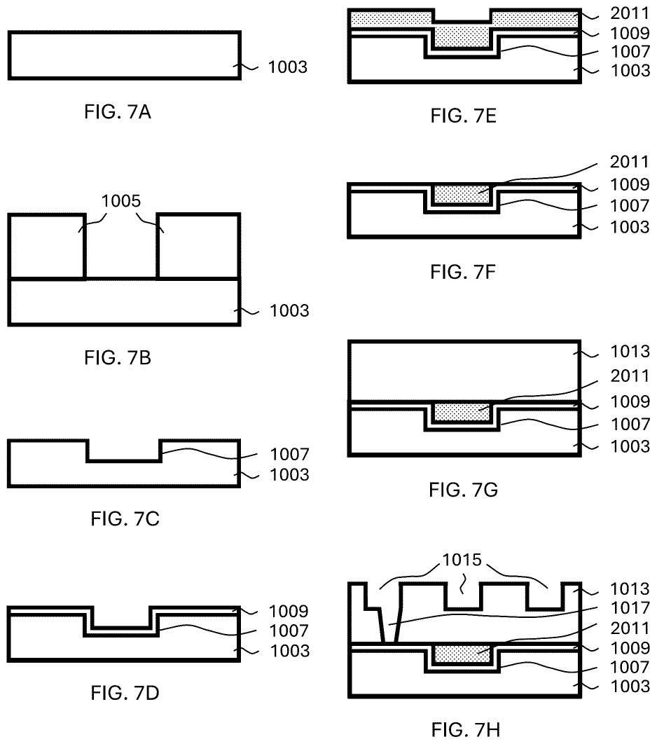

Referring now to FIGS. 7A-7H, according to some aspects, in the method of manufacturing a semiconductor structure, according to the embodiment of FIG. 3, a first metal wire 1003 can be formed, as shown in FIG. 7A. The first metal wire 1003 can be formed in a first wiring layer (e.g., first wiring layer 1001 as illustrated in FIG. 3) on a substrate (not shown for simplicity) of the semiconductor structure utilizing processes known in the art (e.g., Damascene process, etc.).

As further illustrated in FIG. 7B, a patterned mask 1005 can be formed on the first metal wire 1003. The patterned mask 1005 can be formed to provide a template for etching of the first metal wire 1003 utilizing processes and materials similar to the patterned mask 1005 previously described in reference to FIG. 6B.

As shown in FIG. 7C, the patterned mask (e.g., patterned mask 1005 as shown in FIG. 7B) and a portion of the first metal wire 1003 can be etched, removing the patterned mask and a selective portion of the first metal wire 1003 forming a recess 1007 in the first metal wire 1003. The recess 1007 can be etched utilizing processes previously described in reference to FIG. 6C. Dimensions of the recess 1007, depth and width, can correspond to a minimal sufficient insulation between the first metal wire 1003 and an adjacent high voltage net metal wire (e.g., third metal wire 1023 as shown in FIG. 3), as described in reference to FIG. 3 (and as further described in reference to FIG. 2).

In some embodiments, a capping layer 1009 can be deposited over the first metal wire 1003, as illustrated in FIG. 7D. The capping layer 1009 can be deposited similar to that described in reference to FIG. 6D and utilizing processes previously described in reference to FIG. 6D.

Turning to FIG. 7E, in some embodiments, a dielectric material 2011 can be deposited over the capping layer 1009. The dielectric material 2011 can be any dielectric suitable for use as an interlayer dielectric including low-k or high-k dielectrics that are compatible with CMP control. In some embodiments, the dielectric material 2011 can be made of a stronger dielectric than a subsequent deposited interlayer dielectric, though examples are not so limiting. That is, in some embodiments, the dielectric material 2011 can be made of a material that includes a greater insulating characteristic and/or a greater resistance to electrical breakdown than that of a subsequent deposited interlayer dielectric.

Continuing on to FIG. 7F, chemical mechanical polishing (CMP) and/or planarization processes can be performed on the dielectric material 2011, removing excess dielectric material 2011. Accordingly, the dielectric material 2011 can be removed from a portion of the capping layer 1009 while leaving the dielectric material 2011 that fills an area of the recess 1007 of the first metal wire 1003 between the capping layer 1009 and a subsequent interlayer dielectric (e.g., ILD 1013 as shown in FIG. 7G).

The interlayer dielectric (ILD) 1013 can be deposited over the capping layer 1009 and the dielectric material 2011, as shown in FIG. 7G. The ILD 1013 can be made of materials similar to those described in reference to FIG. 6F and can be deposited utilizing techniques similar to those described in reference to FIG. 6F.

A hard mask can be formed and patterned on the ILD 1013 utilizing processes previously described in reference to FIG. 6G. Based on the patterning, the hard mask and ILD 1013 can be etched to create a plurality of wiring patterns, such as the trench 1015 and the via 1017 patterning as shown in FIG. 7H. In some embodiments, any remaining hard mask can be removed during or after completion of the etching process.

Referring back to FIG. 3. Utilizing processes and materials similar to those described in reference to FIG. 2, metal can be deposited, filling the plurality of wiring patterns (e.g., trench 1015 and via 1017 patterning as shown in FIG. 7H) and forming the second wiring layer 1019. In some examples, prior to depositing of the metal, a barrier layer (not shown) can be deposited on the ILD 1013 utilizing process similar to those described in reference to FIG. 2.

As shown in FIG. 3, the deposited metal can form the second metal wire 1021, the third metal wire 1023, the fourth metal wire 1025, and the via 1027. Excessive metal (and barrier layer in embodiments that include a barrier layer) deposited on the ILD 1013 can be removed using previously described processes in reference to FIG. 2.

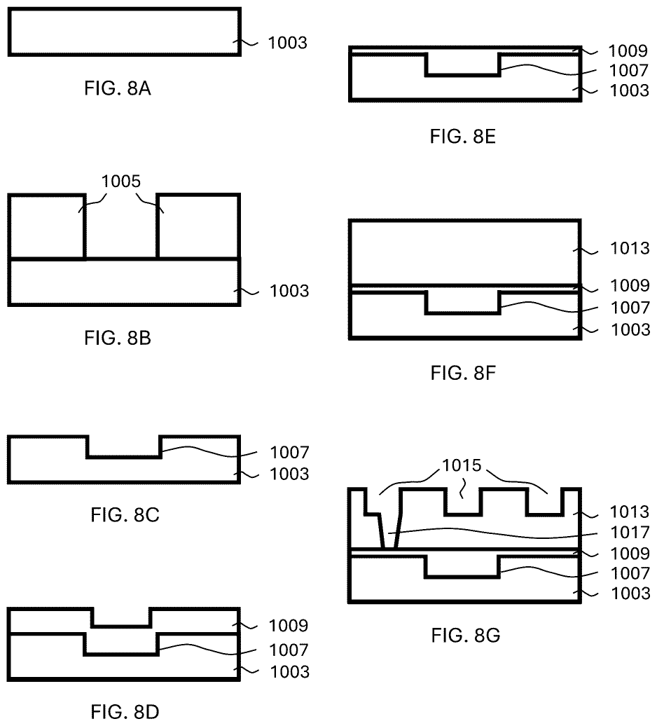

Referring now to FIGS. 8A-8G, according to some aspects, in the method of manufacturing a semiconductor structure, according to the embodiment of FIG. 4, a first metal wire 1003 can be formed, as shown in FIG. 8A. The first metal wire 1003 can be formed in a first wiring layer of a semiconductor structure, as previously described in reference to FIG. 6A.

As illustrated in FIG. 8B, a patterned mask 1005 can be formed on the first metal wire 1003 to provide a template for etching of the first metal wire 1003. Continuing to FIG. 8C, the patterned mask (e.g., patterned mask 1005 as shown in FIG. 8B) and a portion of the first metal wire 1003 can be etched, removing the patterned mask and a selective portion of the first metal wire 1003 forming a recess 1007 in the first metal wire 1003. Dimensions of the recess 1007, depth and width, can correspond to a minimal sufficient insulation between the first metal wire 1003 and an adjacent high voltage net metal wire (e.g., third metal wire 1023 as shown in FIG. 4), as described in reference to FIG. 4 (and as further described in reference to FIG. 2).

In some embodiments, a capping layer 1009 can be deposited over the first metal wire 1003, as illustrated in FIG. 8D. The capping layer 1009 can be deposited so as to fill the recess 1007 of the first metal wire 1003. The capping layer 1009 can be chemical mechanical polished (CMP) and/or planarized, removing a portion of the capping layer 1009, as shown in FIG. 8E. Accordingly, the remaining capping layer 1009 can cover a length of the first metal wire 1003 and fill the recess 1007 of the first metal wire 1003.

Turning to FIG. 8F, an interlayer dielectric (ILD) 1013 can be deposited over the capping layer 1009. A hard mask can be formed and patterned on the ILD 1013. Based on the patterning, the hard mask and ILD 1013 can be etched to create a plurality of wiring patterns, such as a trench 1015 and a via 1017 patterning as shown in FIG. 8G. In some embodiments, any remaining hard mask can be removed during or after completion of the etching process.

Referring back to FIG. 4. Utilizing processes and materials similar to those described in reference to FIG. 2, metal can be deposited, filling the plurality of wiring patterns (e.g., trench 1015 and via 1017 patterning as shown in FIG. 8G) and forming the second wiring layer 1019. In some examples, prior to depositing of the metal, a barrier layer (not shown) can be deposited on the ILD 1013. The deposited metal can form the second metal wire 1021, the third metal wire 1023, the fourth metal wire 1025, and the via 1027. Excessive metal (and barrier layer in embodiments that include a barrier layer) deposited on the ILD 1013 can be removed.

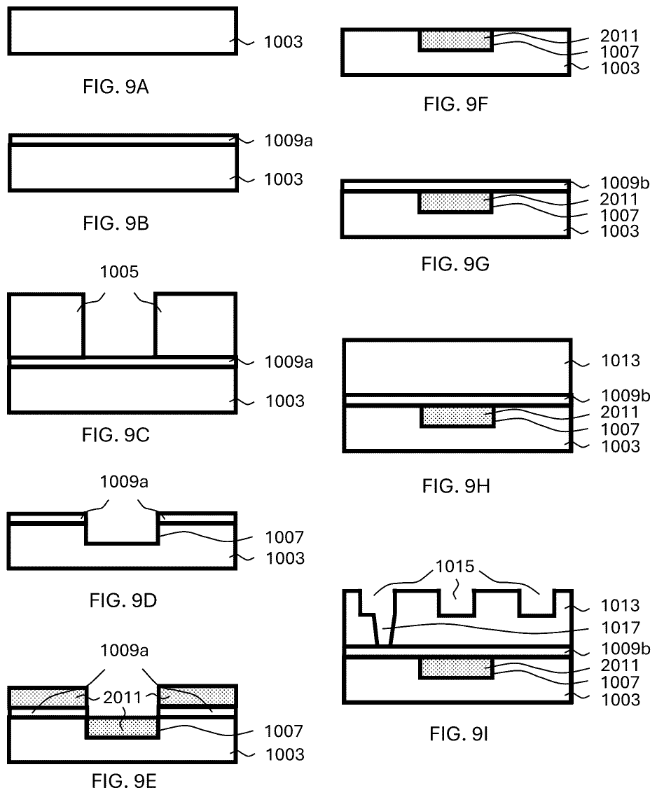

Referring now to FIGS. 9A-9I, according to some aspects, in the method of manufacturing a semiconductor structure, according to the embodiment of FIG. 5, a first metal wire 1003 can be formed, as shown in FIG. 9A. The first metal wire 1003 can be formed in a first wiring layer of a semiconductor structure, as previously described in reference to FIG. 6A.

In some embodiments, as illustrated in FIG. 9B, a first capping layer 1009a can be deposited on the first metal wire 1003. The first capping layer 1009a can be deposited utilizing processes as previously described in reference to the capping layer 1009 in FIG. 6D. Moving on to FIG. 9C, a patterned mask 1005 can be formed on the first capping layer 1009a. The patterned mask 1005 can be formed to provide a template for etching of the first capping layer 1009a and the first metal wire 1003.

As shown in FIG. 9D, the patterned mask (e.g., patterned mask 1005 as shown in FIG. 9C) and a portion of both the first capping layer 1009a and the first metal wire 1003 can be etched, removing the patterned mask and a selective portion of both the first capping layer 1009a and the first metal wire 1003, forming a gap in the first capping layer 1009a and a recess 1007 in the first metal wire 1003. The recess 1007, and consequently the gap, can be etched to dimensions, depth and/or width, corresponding to a minimal sufficient insulation between the first metal wire 1003 and an adjacent high voltage net metal wire (e.g., third metal wire 1023 as shown in FIG. 5), as described in reference to FIG. 5 (and as further described in reference to FIG. 2).

Turning to FIG. 9E, in some embodiments, a dielectric material 2011 can be deposited over the first capping layer 1009a and in the recess 1007 of the first metal wire 1003. In some embodiments (as described in reference to FIG. 7E), the dielectric material 2011 can be made of a stronger dielectric than a subsequent deposited interlayer dielectric, though examples are not so limited. Continuing to FIG. 9F, chemical mechanical polishing (CMP) and/or planarization processes can be performed on the dielectric material 2011 and the first capping layer 1009a, removing the first capping layer 1009a and a portion of the dielectric material 2011, leaving the dielectric material 2011 filling the recess 1007 of the first metal wire 1003.

In some embodiments, a second capping layer 1009b can be deposited over the first metal wire 1003 and the dielectric material 2011, as illustrated in FIG. 9G. The second capping layer 1009b can be deposited utilizing processes previously described in reference to the capping layer 1009 in FIG. 6D.

An interlayer dielectric (ILD) 1013 can be deposited over the second capping layer 1009b, as shown in FIG. 9H. A hard mask can be formed and patterned on the ILD 1013 utilizing processes previously described in reference to FIG. 6G. Based on the patterning, the hard mask and ILD 1013 can be etched to create a plurality of wiring patterns, such as a trench 1015 and a via 1017 patterning as shown in FIG. 9I. In some embodiments, any remaining hard mask can be removed during or after completion of the etching process.

Referring back to FIG. 5. Utilizing processes and materials similar to those described in reference to FIG. 2, metal can be deposited, filling the plurality of wiring patterns (e.g., trench 1015 and via 1017 patterning as shown in FIG. 9I) and forming the second wiring layer 1019. In some examples, prior to depositing of the metal, a barrier layer (not shown) can be deposited on the ILD 1013 utilizing process similar to those described in reference to FIG. 2.

As shown in FIG. 5, the deposited metal can form the second metal wire 1021, the third metal wire 1023, the fourth metal wire 1025, and the via 1027. Excessive metal (and barrier layer in embodiments that include a barrier layer) deposited on the ILD 1013 can be removed using previously described processes in reference to FIG. 2.

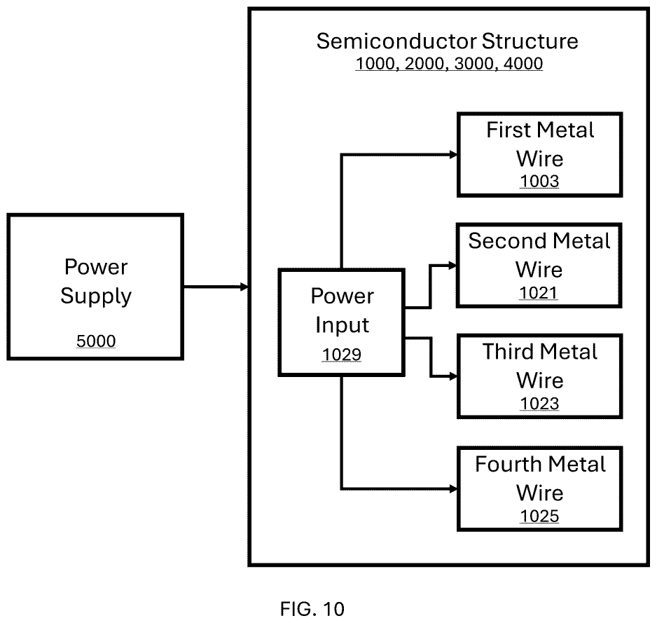

Turning now to FIG. 10, a power supply 5000 can be coupled to an exemplary semiconductor structure 1000, 2000, 3000, 4000. According to some aspects, the semiconductor structure 1000, 2000, 3000, 4000 can include a power input 1029. The power supply 5000 can be electrically coupled to the power input 1029 of the semiconductor structure 1000, 2000, 3000, 4000. In some embodiments, the power input 1029 can be electrically coupled to a first metal wire 1003, a second metal wire 1021, a third metal wire 1023, and/or a fourth metal wire 1025 of the semiconductor structure 1000, 2000, 3000, 4000. Though one power input 1029 is shown, embodiments are not so limited and the semiconductor structure 1000, 2000, 3000, 4000 can include a plurality power inputs in which any power input, of the plurality of power inputs, can be shared between various metal wires or can be designated to one metal wire of the semiconductor structure 1000, 2000, 3000, 4000.

It is understood that the skilled artisan knows connection and supply of power to the semiconductor structure 1000, 2000, 3000, 4000 to cause voltages to appear in metal wires of the semiconductor structure 1000, 2000, 3000, 4000. As such, the power supply 5000 can supply a specified voltage to the first metal wire 1003, the second metal wire 1021, the third metal wire 1023, and/or the fourth metal wire 1025 by way of the power input 1029. Specifically, the power supply 5000 can supply a first amount of voltage to the first metal wire 1003 and the fourth metal wire 1025 (as the fourth metal wire 1025 can be directly connected to the first metal wire 1003 though a via 1027, as described in reference to FIGS. 2-5). Further, the power supply 5000 can supply a second amount of voltage to the second metal wire 1021 and a third amount of voltage to the third metal wire 1023. In some embodiments, a differential between the amount of voltage supplied to the first metal wire 1003 and the third metal wire 1023 can be significantly greater than a differential between the amount of voltage supplied to the first metal wire 1003 and the second metal wire. The skilled artisan is familiar with connecting power supplies to integrated circuits and distributing power within integrated circuits.

Advantageously, as previously described in detail herein, a semiconductor structure can include a low voltage net and/or a high voltage net circuit in a single wiring layer and in adjacent wiring layers, combining varying circuitry within the single wiring layer without increasing a distance between adjacent wiring layers, an overall thickness of the semiconductor structure, length of vias between wiring layers, nor jeopardizing functionality and reliability of the semiconductor structure.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far (reference characters refer to the drawings discussed above), it will be appreciated that, in general terms, an exemplary semiconductor structure 1000, 2000, 3000, 4000 includes a first wiring layer 1001 having a first metal wire 1003, the first metal wire 1003 having a recess 1007 defined therein; a second wiring layer 1019 having a second metal wire 1021 spaced a first distance A from the first metal wire 1003, and a third metal wire 1023 spaced a second distance B from the first metal wire 1003, the third metal wire 1023 being opposite the recess 1007 of the first metal wire 1003; and an interlayer dielectric (ILD) 1013 separating the first wiring layer 1001 from the second wiring layer 1019 and the second metal wire 1021 from the third metal wire 1023, in which a voltage differential tolerance between the first metal wire 1003 and the third metal wire 1023 is greater than a voltage differential tolerance between the first metal wire 1003 and the second metal wire 1021.

Optionally, the second distance B can be greater than the first distance A and a width W of the recess 1007 can be greater than a width of the third metal wire 1023.

Further, optionally, preclusion of a time-dependent dielectric breakdown (TDDB) can be greater between the first metal wire 1003 and the third metal wire 1023 than between the first metal wire 1003 and the second metal wire 1021.

In still further options, the semiconductor structure 1000, 2000, 3000, 4000 can have a power input 1029, in which a power supply 5000 can regulate voltages applied to the first metal wire 1003, the second metal wire 1021, and the third metal wire 1023 and a differential between the voltages applied to the first metal wire 1003 and the third metal wire 1023 can be greater than a differential between the voltages applied to the first metal wire 1003 and the second metal wire 1021.

Continuing with options, the semiconductor structure 1000, 2000, 3000, 4000 can include a capping layer 1009 separating the first metal wire 1003 from the ILD 1013.

Optionally, a thickness of the ILD 1013 between the third metal wire 1023 and the capping layer 1009 can be greater than a thickness of the ILD 1013 between the second metal wire 1021 and the capping layer 1009.

In still further options, the semiconductor structure 2000 can include a dielectric material 2011, wherein the capping layer 1009 partially fills the recess 1007, the dielectric material 2011 fills a remaining area of the recess 1007 not filled by the capping layer 1009, and the capping layer 1009 further separates the first metal wire 1003 from the dielectric material 2011.

In some options, the capping layer 1009 can fill the recess 1007 of the first metal wire 1003.

Still, in further options, the semiconductor structure 4000 can include a dielectric material 2011, wherein the dielectric material 2011 fills the recess 1007 of the first metal wire 1003 and the capping layer 1009 further separates the dielectric material 2011 from the ILD 1013.

In accordance with further aspects of the invention, a semiconductors structure 1000, 2000, 3000, 4000 includes a first wiring layer 1001 having a first metal wire 1003, the first metal wire 1003 being a first voltage net structure and having a recess 1007 defined therein; a second wiring layer 1019 having a second metal wire 1021, the second metal wire 1021 being a second voltage net structure, in which the second metal wire 1021 is opposite a non-recessed portion of the first metal wire 1003, and a third metal wire 1023, the third metal wire 1023 being a third voltage net structure, in which the third metal wire 1023 is opposite the recess 1007 of the first metal wire 1003, in which a distance B between the third metal wire 1023 and the recess 1007 of the first metal wire 1003 is greater than a distance A between the second metal wire 1021 and the non-recessed portion of the first metal wire 1003; an interlayer dielectric (ILD) 1013 separating the first wiring layer 1001 from the second wiring layer 1019 and the second metal wire 1021 from the third metal wire 1023; and a capping layer 1009 separating the first metal wire 1003 of the first wiring layer 1001 from the ILD 1013. A voltage differential tolerance between the first metal wire 1003 and the third metal wire 1023 is greater than a voltage differential tolerance between the first metal wire 1003 and the second metal wire 1021 based on resistance to time-dependent dielectric breakdown (TDDB).

Optionally, a width W of the recess 1007 can be greater than a width of the third metal wire 1023.

Further, optionally, a thickness of the ILD 1013 between the third metal wire 1023 and the capping layer 1009 can be greater than a thickness of the ILD 1013 between the second metal wire 1021 and the capping layer 1009.

In further options, the semiconductor structure 2000 can include a dielectric material 2011, wherein the capping layer 1009 partially fills the recess 1007, the dielectric material 2011 fills a remaining area of the recess 1007 not filled by the capping layer 1009, and the capping layer 1009 further separates the first metal wire 1003 from the dielectric material 2011.

In still further options, the capping layer 1009 can fill the recess 1007 of the first metal wire 1003.

Continuing with options, the semiconductor structure 4000 can include a dielectric material 2011, wherein the dielectric material 2011 fills the recess 1007 of the first metal wire 1003 and the capping layer 1009 further separates the dielectric material 2011 from the ILD 1013.

In accordance with further aspects of the invention, an exemplary method of forming a semiconductor structure 1000, 2000, 3000, 4000 includes forming a first wiring layer 1001 having a first metal wire 1003, the first metal wire 1003 being a first voltage net structure; etching a recess 1007 in the first metal wire 1003; depositing a capping layer 1009 over the first metal wire 1003 and the recess 1007 of the first metal wire 1003; depositing an interlayer dielectric (ILD) 1013 on the capping layer 1009; and forming a second wiring layer 1019 in the ILD 1013, in which forming the second wiring layer 1019 includes depositing a hard mask on the ILD 1013 and etching, within the ILD 1013, a plurality of wiring patterns (see trench 1015), in which a first wiring pattern of the plurality of wiring patterns (see trench 1015) is etched opposite a non-recessed portion of the first metal wire 1003 and a second wiring pattern of the plurality of wiring patterns (see trench 1015) is etched opposite a recessed portion 1007 of the first metal wire 1003. Further steps include filling the first wiring pattern to form a second metal wire 1021 of the semiconductor structure 1000, 2000, 3000, 4000, the second metal wire 1021 being a second voltage net structure; and filling the second wiring pattern to form a third metal wire 1023 of the semiconductor structure, 1000, 2000, 3000, 4000. The steps are carried out such that, subsequent to filling the second wiring pattern, the semiconductor structure is configured such that: a first voltage differential tolerance is provided between the first voltage net structure and the second voltage net structure; a second voltage differential tolerance is provided between the first voltage net structure and the third voltage net structure; and the second voltage differential tolerance is greater than the first voltage differential tolerance based on resistance to time-dependent dielectric breakdown (TDDB).

Optionally, the capping layer 1009 can be in physical contact with the first metal wire 1003 and the recess 1007 of the first metal wire 1003.

Further, optionally, the semiconductor structure 2000 can include, prior to depositing the ILD 1013, depositing a dielectric material 2011 on the capping layer 1009, filling the recess 1007 of the first metal wire 1003.

In optional further aspects, depositing the capping layer 1009 includes filling the recess 1007 of the first metal wire 1003 with the capping layer 1009.

In still further options, the semiconductor structure 4000 can include, prior to depositing the capping layer 1009, filling the recess 1007 of the first metal wire 1003 with a dielectric material 2011.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from phase change memory cells with highly oriented PCM structure aligned to highly oriented, thermoelectric material, seed layer in phase change memory arrays, and the like.

An integrated circuit in accordance with aspects of the present inventions can be employed in essentially any application and/or electronic system where multiple wiring layers including both low voltage net structures and high voltage net structures, and the like, as disclosed herein, would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession can, in fact, be executed substantially concurrently, or certain steps can sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom,” “top,” “above,” “over,” “under,” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a first wiring layer comprising a first metal wire, the first metal wire having a recess defined therein;
a second wiring layer comprising:
a second metal wire spaced a first distance from the first metal wire; and
a third metal wire spaced a second distance from the first metal wire, the third metal wire being opposite the recess of the first metal wire; and
an interlayer dielectric (ILD) separating the first wiring layer from the second wiring layer and the second metal wire from the third metal wire,
wherein a voltage differential tolerance between the first metal wire and the third metal wire is greater than a voltage differential tolerance between the first metal wire and the second metal wire.

2. The semiconductor structure of claim 1, wherein the second distance is greater than the first distance and a width of the recess is greater than a width of the third metal wire.

3. The semiconductor structure of claim 1, wherein preclusion of a time-dependent dielectric breakdown (TDDB) is greater between the first metal wire and the third metal wire than between the first metal wire and the second metal wire.

4. The semiconductor structure of claim 1, further comprising a power input, wherein a power supply regulates voltages applied to the first metal wire, the second metal wire, and the third metal wire and a differential between the voltages applied to the first metal wire and the third metal wire is greater than a differential between the voltages applied to the first metal wire and the second metal wire.

5. The semiconductor structure of claim 1, further comprising a capping layer separating the first metal wire from the ILD.

6. The semiconductor structure of claim 5, wherein a thickness of the ILD between the third metal wire and the capping layer is greater than a thickness of the ILD between the second metal wire and the capping layer.

7. The semiconductor structure of claim 5, further comprising a dielectric material, wherein the capping layer partially fills the recess, the dielectric material fills a remaining area of the recess not filled by the capping layer, and the capping layer further separates the first metal wire from the dielectric material.

8. The semiconductor structure of claim 5, wherein the capping layer fills the recess of the first metal wire.

9. The semiconductor structure of claim 5, further comprising a dielectric material, wherein the dielectric material fills the recess of the first metal wire and the capping layer further separates the dielectric material from the ILD.

10. A semiconductor structure comprising:
a first wiring layer comprising a first metal wire, the first metal wire being a first voltage net structure and having a recess defined therein;
a second wiring layer comprising:
a second metal wire, the second metal wire being a second voltage net structure, wherein the second metal wire is opposite a non-recessed portion of the first metal wire; and
a third metal wire, the third metal wire being a third voltage net structure, wherein the third metal wire is opposite a recessed portion of the first metal wire,
wherein a distance between the third metal wire and the recessed portion of the first metal wire is greater than a distance between the second metal wire and the non-recessed portion of the first metal wire;
an interlayer dielectric (ILD) separating the first wiring layer from the second wiring layer and the second metal wire from the third metal wire; and
a capping layer separating the first metal wire of the first wiring layer from the ILD,
wherein a voltage differential tolerance between the first metal wire and the third metal wire is greater than a voltage differential tolerance between the first metal wire and the second metal wire based on resistance to time-dependent dielectric breakdown (TDDB).

11. The semiconductor structure of claim 10, wherein a width of the recess is greater than a width of the third metal wire.

12. The semiconductor structure of claim 10, wherein a thickness of the ILD between the third metal wire and the capping layer is greater than a thickness of the ILD between the second metal wire and the capping layer.

13. The semiconductor structure of claim 10, further comprising a dielectric material, wherein the capping layer partially fills the recess, the dielectric material fills a remaining area of the recess not filled by the capping layer, and the capping layer further separates the first metal wire from the dielectric material.

14. The semiconductor structure of claim 10, wherein the capping layer fills the recess of the first metal wire.

15. The semiconductor structure of claim 10, further comprising a dielectric material, wherein the dielectric material fills the recess of the first metal wire and the capping layer further separates the dielectric material from the ILD.

16. A method of forming a semiconductor structure comprising the steps of:
forming a first wiring layer comprising a first metal wire, the first metal wire being a first voltage net structure;
etching a recess in the first metal wire;
depositing a capping layer over the first metal wire and the recess of the first metal wire;
depositing an interlayer dielectric (ILD) on the capping layer; and
forming a second wiring layer in the ILD, wherein forming the second wiring layer comprises:
depositing a hard mask on the ILD and etching, within the ILD, a plurality of wiring patterns, wherein a first wiring pattern of the plurality of wiring patterns is etched opposite a non-recessed portion of the first metal wire and a second wiring pattern of the plurality wiring patterns is etched opposite a recessed portion of the first metal wire;
filling the first wiring pattern to form a second metal wire of the semiconductor structure, the second metal wire being a second voltage net structure; and
filling the second wiring pattern to form a third metal wire of the semiconductor structure, the third metal wire being a third voltage net structure;
wherein the steps are carried out such that, subsequent to filling the second wiring pattern, the semiconductor structure is configured such that:
a first voltage differential tolerance is provided between the first voltage net structure and the second voltage net structure;
a second voltage differential tolerance is provided between the first voltage net structure and the third voltage net structure; and
the second voltage differential tolerance is greater than the first voltage differential tolerance based on resistance to time-dependent dielectric breakdown (TDDB).

17. The method of claim 16, wherein the capping layer is in physical contact with the first metal wire and the recess of the first metal wire.

18. The method of claim 17, further comprising, prior to depositing the ILD, depositing a dielectric material on the capping layer, filling the recess of the first metal wire.

19. The method of claim 17, wherein depositing the capping layer comprises filling the recess of the first metal wire with the capping layer.

20. The method of claim 16, further comprising, prior to depositing the capping layer, filling the recess of the first metal wire with a dielectric material.
